(19) United States
(12) Patent Application Publication
(10) Pub. No.: US 2024/0128439 A1
(43) Pub. Date: Apr. 18, 2024

(54) CYCLOHEXASILANE FOR ELECTRODES

(71) Applicant: THE CORETEC GROUP INC., Ann Arbor, MI (US)

(72) Inventor: Ramez Ahmed Elgammal, Knoxville, TN (US)

(21) Appl. No.: 18/278,245

(22) PCT Filed: Feb. 22, 2022
(86) PCT No.: PCT/US2022/017223

§ 371 Date: Aug. 22, 2023

Related U.S. Application Data
(60) Provisional application No. 63/152,016, filed on Feb. 22, 2021.

(51) Int. Cl. H01M 4/1397; C01B 21/068; C23C 16/24; C23C 16/34; C23C 16/50; H01M 4/04; H01M 4/58

(52) U.S. Cl. CPC H01M 4/1397; C01B 21/0682; C23C 16/24; C23C 16/345; C23C 16/50; H01M 4/0428; H01M 4/58; C01P 2002/54; C01P 2004/16; C01P 2006/40

(57) ABSTRACT

A silicon nitride (SiNₓ) based anode is produced by combining a silicon precursor that includes cyclohexasilane and a nitrogen precursor. A doped silicon based anode is produced by combining a silicon precursor that includes cyclohexasilane and a dopant precursor selected from a boron precursor, a nitrogen precursor, a sulfur precursor, an aluminum precursor, a phosphorous precursor, and combinations thereof. Silicon nanowires are produced by depositing metallic nanoparticles on surfaces of carbon support particles and then depositing silicon from cyclohexasilane onto the carbon support particles. The silicon preferentially deposits onto the metallic nanoparticles to form silicon nanowires that extend off of the metallic nanoparticle away from the surfaces.

### BACKGROUND

Next generation lithium-ion batteries (LIBs) will require electrodes with high energy and power density, rapid charging, and long-term cycling stability. Silicon is under consideration as an electrode material because of its high theoretical capacity, relatively large natural abundance, and low discharge potential. For example, amorphous silicon nitride films can be deposited by plasma enhanced physical vapor deposition from gaseous silane (SiH₄) and ammonia (NH₃). Amorphous silicon nitride, however, exhibits large volumetric changes during lithiation and delithiation that can contribute to stress-induced fracture and/or delamination from a substrate.

### SUMMARY

A method according to an example of the present disclosure includes producing a silicon nitride (SiNₓ) based anode by combining a silicon precursor that includes cyclohexasilane and a nitrogen precursor.

In a further embodiment of the foregoing embodiment, the nitrogen precursor is selected from the group consisting of ammonia, hydrazine, methylamine, ethylamine, acetonitrile, aniline, N,N′-Di-t-butyl-2,3-diaminobutane, and combinations thereof.

In a further embodiment of any of the foregoing embodiments, the nitrogen precursor is selected from the group consisting of hydrazine, methylamine, ethylamine, acetonitrile, aniline, N,N′-Di-t-butyl-2,3-diaminobutane, and combinations thereof.

In a further embodiment of any of the foregoing embodiments, the silicon nitride is a thin film, nanowires, or nanoparticle.

A method according to an example of the present disclosure includes producing a doped silicon based anode by combining a silicon precursor that includes cyclohexasilane and a dopant precursor selected from the group consisting of a boron precursor, a nitrogen precursor, a sulfur precursor, an aluminum precursor, a phosphorous precursor, and combinations thereof.

In a further embodiment of any of the foregoing embodiments, the dopant precursor is the boron precursor and is selected from the group consisting of diborane, trimethyl borane, triisopropyl borate, and combinations thereof.

In a further embodiment of any of the foregoing embodiments, the dopant precursor is the aluminum precursor and is selected from the group consisting of trimethyl aluminum, triisobutyl, tris(dimethylamido) aluminum, and combinations thereof.

In a further embodiment of any of the foregoing embodiments, the dopant precursor is the phosphorous precursor and is selected from the group consisting of phosphorous oxychloride (POCl₃), trimethyl phosphate (PO(OCH₃)₃), triethyl phosphate (PO(OCH₂CH₃)₃), white (P₄) and red phosphorous, triphenylphosphine (P(C₆H₅)₃), white phosphorous, red phosphorous, polyphosphide derived from red phosphorous, and combinations thereof.

In a further embodiment of any of the foregoing embodiments, the dopant precursor is the sulfur precursor and is selected from the group consisting of elemental sulfur, dimethyl sulfide, and combinations thereof.

In a further embodiment of any of the foregoing embodiments, the dopant precursor is selected from the group consisting of diborane, trimethyl borane, triisopropyl borate, trimethyl aluminum, triisobutyl, tris(dimethylamido) aluminum, phosphorous oxychloride (POCl₃), trimethyl phosphate (PO(OCH₃)₃), triethyl phosphate (PO(OCH₂CH₃)₃), white (P₄) and red phosphorous, triphenylphosphine (P(C₆H₅)₃), white phosphorous, red phosphorous, polyphosphide derived from red phosphorous, elemental sulfur, dimethyl sulfide, and combinations thereof.

In a further embodiment of any of the foregoing embodiments, the doped silicon anode has a dopant level of 10¹⁹-10²¹ atoms/cm³.

In a further embodiment of any of the foregoing embodiments, the silicon nitride is a thin film, nanowires, or nanoparticle.

A method according to an example of the present disclosure includes depositing metallic nanoparticles on surfaces of carbon support particles, and depositing silicon from cyclohexasilane onto the carbon support particles. The silicon preferentially deposits onto the metallic nanoparticles to form silicon nanowires that extend off of the metallic nanoparticle away from the surfaces.

In a further embodiment of any of the foregoing embodiments, the metallic nanoparticles are selected from the group consisting of silver, platinum, gold, iron, titanium, aluminum, copper, lead, titanium, tin, manganese, and combinations thereof.

The present disclosure may include any one or more of the individual features disclosed above and/or below alone or in any combination thereof.

### BRIEF DESCRIPTION OF THE DRAWINGS

The various features and advantages of the present disclosure will become apparent to those skilled in the art from the following detailed description. The drawings that accompany the detailed description can be briefly described as follows.

FIG. 1 illustrates an example reaction for synthesis of SiNₓ.

FIG. 2 illustrates an example of a battery that employs a SiNₓ anode.

FIG. 3 illustrates an example of the processing of cyclohexasilane in the presence of a dopant precursor to produce doped silicon.

FIG. 4 illustrates an example method producing silicon nanowires on carbon support particles.

### DETAILED DESCRIPTION

Cyclohexasilane (C₆H₁₂), or “CHS,” is a clear, colorless liquid at room temperature and can be processed as a liquid or a gas. Application of heat and/or ultra-violet radiation converts the CHS to polysilane. Further thermal processing converts the polysilane to amorphous silicon, and, if desired, subsequent thermal treatment converts the amorphous silicon to crystalline silicon. Therefore, especially where there are concerns for use of gaseous silane (SiH₄), CHS may serve as silicon precursor for rapid processing at relatively low temperatures (e.g., room temperature). Below are exemplary implementations of CHS for silicon nitride electrodes.

Silicon Nitride Electrode

Silicon nitride (Si₃N₄) and substoichometric silicon nitride derivatives (SiNₓ) are an alternative to silicon and silicon/carbon composites in electrodes, particularly anodes, in lithium ion batteries. An example electrochemical reaction for a silicon nitride based anode is shown below. The term “based” as used in “silicon nitride based anode” means that the SiNx is the parent material in which reversible electrochemical lithiation and delithiation occur.

$${SiN}_{x} + {nLi}^{+} {ne}^{-} {\to }^{Conversation} matrix + {Li}_{3.75} Si {⟷}^{cycling} matrix + Si + 3.75 {Li}^{+} + 3.75 {e}^{-}$$

One technique for manufacturing silicon nitride is plasma enhanced chemical vapor deposition (PECVD) from precursors of monosilane (SiH₄) and ammonia (NH₃). PECVD-derived materials are, however, limited to thin films. Example techniques disclosed herein utilize cyclohexasilane (CHS) to produce nanostructured powders, thin films, or nanowires, which may facilitate enhanced resistance to delamination that is observed with monosilane-derived silicon nitride.

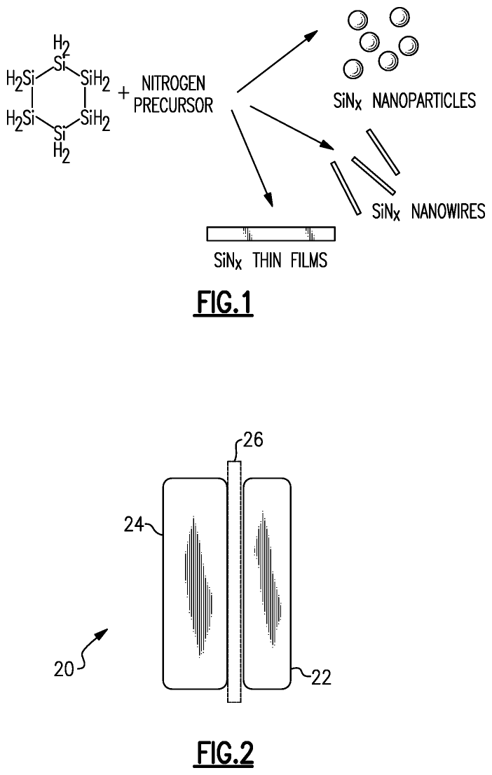

FIG. 1 illustrates an example reaction for synthesis of SiNₓ in the form of nanoparticles, nanowires, or thin films using CHS, where x is from 0.2 to 0.8 (x=0.2-0.8). Nanoparticles may be prepared by a variety of methods, although solution-based techniques may be desired for process flexibility. For example, CHS is mixed with hydrocarbon or ethereal solvent and then heated (e.g., above 100° C.) to thermochemically produce nanoparticle growth. Heating may include, but is no limited to, microwave heating or ultra-violet irradiation. Thin films may be grown by a variety of methods, such as PECVD or atomic layer deposition (ALD) at temperatures in a range of 100-500° C. and at a pressure of 50 mTorr to 100 Torr.

A nitrogen precursor provides the nitrogen for the silicon nitride. For example, the nitrogen precursor includes, but is not limited to, ammonia, hydrazine, methylamine, ethylamine, acetonitrile, aniline, N,N′-Di-t-butyl-2,3-diaminobutane, or combinations of these. Solution-based synthesis may be conducted by any of the reaction types A.-Q. listed below to produce nanoparticles, nanowires, or thin films of the silicon nitride (SiNₓ) The amount of nitrogen precursor used will be adjusted based on the composition desired end-product and the specific technique that is used. As an example, the range of x in the SiNₓ composition may be used to determine how much nitrogen precursor to use. For instance, the nitrogen precursor is added to the reaction mixture containing the silicon species. In the case of a gas phase reaction, both species are introduced simultaneously into a reactor through different ports.
A. Solution phase reduction
B. Reduction by heterogeneous catalysis
C. Ultraviolet irradiation
D. Laser ablation
E. Sputtering
F. Thermal evaporation
G. Reactive evaporation
H. e-beam evaporation
I. Molecular beam epitaxy
J. Pulse laser ablation
K. Ion implantation
L. PECVD
M. RF-PECVD
N. IC-PCVD
O. HWCVD
P. Cat-CVD
Q. ALD

FIG. 2 illustrates an example battery 20 that employs the silicon nitride (SiNₓ) as SiNₓ anode 22. The SiNₓ anode 22 is situated opposite a cathode 24 (or collectively, electrodes 22/24), with a separator 26 there between. For instance, the separator is a permeable film that electrically isolates the electrodes 22/24 from each other while permitting transport of ionic charge carriers.

Doped Silicon Anodes

Silicon has relatively low electrical conductivity, which is a challenge to obtaining high silicon content and capacity that is desirable in electrodes. Doping silicon can modify the electrochemical properties by changing the binding energy of lithium with silicon. In general, higher doping will give better electrical conductivity and better coulombic efficiency. In crystalline doped silicon, substitutional dopants such as boron (B) change the morphology of the material, transitioning to amorphous during delithiation and lithiation reactions. Such changes in the morphology may contribute to structural damage and poor cycle life in a battery. It has been difficult to obtain high dopant levels, e.g. greater than 10¹⁸ atoms/cm³, using silane precursor (SiH₄).

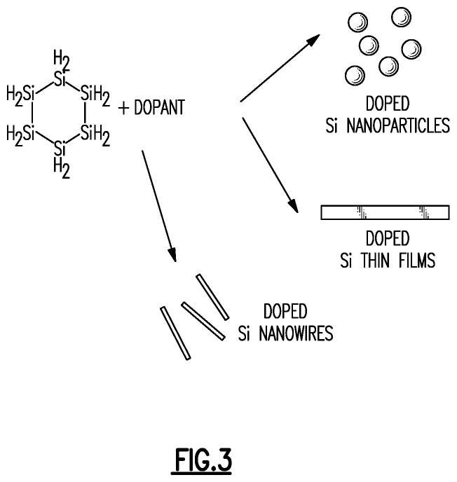

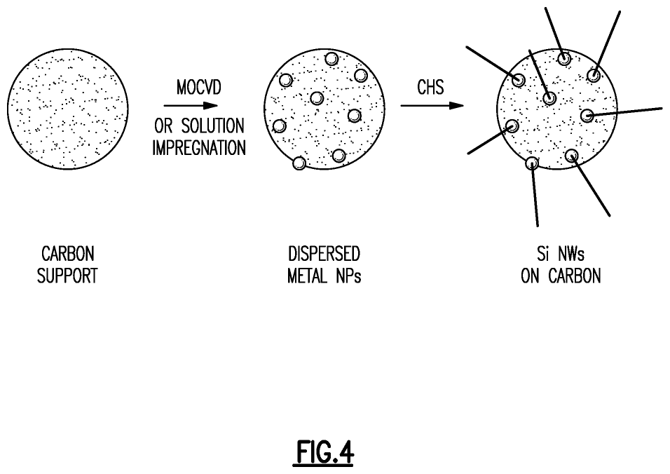

CHS enables higher dopant levels to make p-type materials due to its lower Si—H and Si—Si bond enthalpies compared to incumbent materials. This engenders an enhanced chemical reactivity enabling Si-dopant bonds or insertion of dopant atoms into a lattice. For example, as shown in FIG. 3, CHS is processed in the presence of a dopant precursor to produce doped silicon.

The dopant precursor is selected from a boron precursor, a nitrogen precursor, a sulfur precursor, an aluminum precursor, a phosphorous precursor, or combinations thereof. Nitrogen precursors are the same examples as above: For example, the nitrogen precursor includes, but is not limited to, ammonia, hydrazine, methylamine, ethylamine, acetonitrile, aniline, N,N′-Di-t-butyl-2,3-diaminobutane, or combinations of these. Example of these may include diborane, trimethyl borane, triisopropyl borate, trimethyl aluminum, triisobutyl, tris(dimethylamido) aluminum, phosphorous oxychloride (POCl₃), trimethyl phosphate (PO(OCH₃)₃), triethyl phosphate (PO(OCH₂CH₃)₃), white (P₄) and red phosphorous, triphenylphosphine (P(C₆H₅)₃), white phosphorous, red phosphorous, polyphosphide derived from red phosphorous, elemental sulfur, dimethyl sulfide, and combinations thereof. The dopant precursor or precursors are combined with CHS in amounts to produce dopant levels that are greater than 10¹⁸ atoms/cm³, such as a dopant level in a range 10¹⁹-10²¹ atoms/cm³. The dopant reacts quantitatively with CHS. Thus, for a doping of a given at %, that amount of dopant is added. As an example, consider the reaction of CHS with BH₃. BH₃ may induce a ring-opening reaction to give a —Si—BH₂ bond. The degree of doping in this case can be determined by SIMS (secondary ion mass spectroscopy) and in resulting nanostructure by SEM/EDX using elemental mapping.

In general, cyclohexasilane may react with a phosphorous precursor, such as those listed above, in solution. Choices of solvents include, but are not limited to, hydrocarbons such as decane, ethereal solvents such as diphenyl or dibutyl ether, or glyme based solvents. Nanoparticles may be produced by solvothermal reactions. Thin films may be generated by a vapor phase reaction such as CVD, PVD, or ALD. Doped silicon nanoparticles or thin films may be synthesized by any of the techniques A.-Q. listed above.

Amorphous silicon thin films with well controlled hydrogenation, such as those derived from cyclohexasilane may be readily converted to hydrogenated nanocrystalline (nc-Si:H) thin films with electrical conductivity expected to be in the range of 10⁻² to 10⁻¹ Ω⁻¹cm⁻¹, whereas a-Si:H thin films have electrical conductivities of the order 10⁻⁹ to 10⁻⁷ Ω⁻¹cm⁻¹ with c-Si thin films being intermediate between these two. As an example, cyclohexasilane may be made as a solution in decane and then aerosolized in the presence of a carrier gas with flow rates typically between 100 and 1000 sccm and passed over a heated substrate at 300° C. to 600° C. to produce a thin film. Alternatively, thin films may be grown on a variety of substrates or directly on a current collector using ALD from 20-400° C. for example and pressures between 1 mTorr and 10⁻³ mTorr. nc-Si:H thin films derived from cyclohexasilane may be even better suited for doping because of preferential reactivity and a lower fraction of Si—H surface bonds. Those materials would have even higher electrical conductivities, as domains of crystallinity within an amorphous matrix could facilitate conduction by electron hopping.

Templated Growth of Silicon Nanowires on Carbon

Silicon nanowires on a carbon support particles permits a conductive pathway for a silicon anode. FIG. 4 illustrates an example method of producing such a structure. The carbon support particles may be graphite particles, carbon nanotubes, graphene particles, high surface area carbon granules, or the like. First, metal nanoparticles are deposited onto the carbon support using metal-organic chemical vapor deposition (MOCVD) or solution impregnation followed by reduction. The metal loadings are determined by the amount of metal precursor to carbon stoichiometry and may be in the range of 1-30 wt % depending on the level of dispersion desired. The metal may be silver, platinum, gold, iron, titanium, aluminum, copper, lead, titanium, tin, manganese, or combinations thereof. The metal nanoparticles then serve as a template for deposition and growth of silicon nanowires from CHS. For instance, this is achieved by passivating a dispersed metal nanoparticle with a vapor/gas phase stream of the CHS or by thermochemical reaction of CHS with the metal nanoparticle in solution. For example, the solution phase reaction may be conducted in solvents such as hydrocarbons, ethers, or glymes at temperatures from 20-300° C. and a pressure from 1-10 atm. The method facilitates control over the four factors, discussed below.

First, the silicon loading/content is precisely controlled by the loading of metal onto the carbon support. This means that the growth of the silicon nanowire is highly favored on the metal nanoparticle itself and that dispersion of the silicon nanowires controls the growth. The silicon anchoring on the metal nanoparticle is preferred due to move favorable lattice matching and eutectic annealing with the metal nanoparticle.

Second, the diameter of the silicon nanowire is precisely controlled by the size of metal nanoparticle, with each metal having a characteristic size dependent on nucleation and growth conditions. This means that since the growth of the silicon nanowire is controlled by the nucleation site—the metal nanoparticle—and the diameter of the nanowire is constrained by the diameter of the nanoparticle. The length of the nanowire is controlled by reaction time and temperature.

Third, the electrical conduction pathway between the carbon support and silicon nanowire is mediated through the conductive metal particle. Here, the electron conduction pathway is through the conductive carbon, the conductive metal nanoparticle, and the conductive silicon nanowire, where the axis of electrical conduction is along the growth axis of the silicon nanowire.

Fourth, the method forms a highly dispersed network of silicon nanowires on the carbon support. The degree of dispersion is readily assessed by microscopy such as SEM or TEM and dispersion is controlled by the metal loading. For example, if 5 wt % metal is dispersed on a carbon nanotube with mean diameter of 20 nm and lengths of 300 μm, the interparticle distances would be of the order of 240 nm.

Although a combination of features is shown in the illustrated examples, not all of them need to be combined to realize the benefits of various embodiments of this disclosure. In other words, a system designed according to an embodiment of this disclosure will not necessarily include all of the features shown in any one of the figures or all of the portions schematically shown in the figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from this disclosure. The scope of legal protection given to this disclosure can only be determined by studying the following claims.

What is claimed is:

1. A method comprising:
producing a silicon nitride (SiNₓ) based anode by combining a silicon precursor that includes cyclohexasilane and a nitrogen precursor.

2. The method as recited in claim 1, wherein the nitrogen precursor is selected from the group consisting of ammonia, hydrazine, methylamine, ethylamine, acetonitrile, aniline, N,N′-Di-t-butyl-2,3-diaminobutane, and combinations thereof.

3. The method as recited in claim 1, wherein the nitrogen precursor is selected from the group consisting of hydrazine, methylamine, ethylamine, acetonitrile, aniline, N,N′-Di-t-butyl-2,3-diaminobutane, and combinations thereof.

4. The method as recited in claim 1, wherein the silicon nitride is a thin film, nanowires, or nanoparticle.

5. A method comprising:
producing a doped silicon based anode by combining a silicon precursor that includes cyclohexasilane and a dopant precursor selected from the group consisting of a boron precursor, a nitrogen precursor, a sulfur precursor, an aluminum precursor, a phosphorous precursor, and combinations thereof.

6. The method as recited in claim 5, wherein the dopant precursor is the boron precursor and is selected from the group consisting of diborane, trimethyl borane, triisopropyl borate, and combinations thereof.

7. The method as recited in claim 5, wherein the dopant precursor is the aluminum precursor and is selected from the group consisting of trimethyl aluminum, triisobutyl, tris(dimethylamido) aluminum, and combinations thereof.

8. The method as recited in claim 5, wherein the dopant precursor is the phosphorous precursor and is selected from the group consisting of phosphorous oxychloride (POCl₃), trimethyl phosphate (PO(OCH₃)₃), triethyl phosphate (PO(OCH₂CH₃)₃), white (P₄) and red phosphorous, triphenylphosphine (P(C₆H₅)₃), white phosphorous, red phosphorous, polyphosphide derived from red phosphorous, and combinations thereof.

9. The method as recited in claim 5, wherein the dopant precursor is the sulfur precursor and is selected from the group consisting of elemental sulfur, dimethyl sulfide, and combinations thereof.

10. The method as recited in claim 5, wherein the dopant precursor is selected from the group consisting of diborane, trimethyl borane, triisopropyl borate, trimethyl aluminum, triisobutyl, tris(dimethylamido) aluminum, phosphorous oxychloride (POCl₃), trimethyl phosphate (PO(OCH₃)₃), triethyl phosphate (PO(OCH₂CH₃)₃), white (P₄) and red phosphorous, triphenylphosphine (P(C₆H₅)₃), white phosphorous, red phosphorous, polyphosphide derived from red phosphorous, elemental sulfur, dimethyl sulfide, and combinations thereof.

11. The method as recited in claim 10, wherein the doped silicon anode has a dopant level of 10¹⁹-10²¹ atoms/cm³.

12. The method as recited in claim 11, wherein the silicon nitride is a thin film, nanowires, or nanoparticle.

13. A method comprising:
depositing metallic nanoparticles on surfaces of carbon support particles; and
depositing silicon from cyclohexasilane onto the carbon support particles, the silicon preferentially depositing onto the metallic nanoparticles to form silicon nanowires that extend off of the metallic nanoparticle away from the surfaces.

14. The method as recited in claim 13, wherein the metallic nanoparticles are selected from the group consisting of silver, platinum, gold, iron, titanium, aluminum, copper, lead, titanium, tin, manganese, and combinations thereof.
